(19) United States
(12) Patent Application Publication
(10) Pub. No.: US 2026/0360408 A1
(43) Pub. Date: Nov. 12, 2026

(54) MEMORY DEVICE INCUDING TRANSISTORS AND OPERATING METHOD THEREOF

(71) Applicant: Samsung Electronics Co., Ltd., Suwon-si (KR)

(72) Inventors: Yoonyoung Chung, Pohang-si (KR); Suwon Seong, Pohang-si (KR)

(73) Assignees: Samsung Electronics Co., Ltd., Suwon-si, (KR); POSTECH Research and Business Development Foundation, Pohang-si (KR)

(21) Appl. No.: 19/671,691

(22) Filed: May 8, 2026

(30) Foreign Application Priority Data
May 9, 2025 (KR) 10-2025-0060251
Aug. 18, 2025 (KR) 10-2025-0114240

(51) Int. Cl. G11C 11/408; G11C 11/4091; G11C 11/4094; G11C 11/4096; H10D 30/67

(52) U.S. Cl. CPC G11C 11/4085; G11C 11/4091; G11C 11/4094; G11C 11/4096; H10D 30/6755

(57) ABSTRACT

A memory device includes an in-memory operation circuit connected to a plurality of write word lines, a plurality of read word lines, and a bit line, and including a plurality of bit cells. Each of the plurality of bit cells includes a first transistor connected to the bit line and to a storage node, and a gate connected to a corresponding write word line, at least one second transistor connected to the bit line and to a first node, and a gate connected to the storage node, and a selection transistor connected to the first node and to ground, and a gate connected to a corresponding read word line. A turn-on current of the at least one second transistor corresponds to a reference current value and a multiplication value of the reference current value and a power of two.

### CROSS-REFERENCE TO RELATED APPLICATIONS

This present application claims priority to and the benefit under 35 U.S.C. § 119 (a)-(d) of Korean Patent Application No. 10-2025-0114240, filed on Aug. 18, 2025, in the Korean Intellectual Property Office, and Korean Patent Application No. 10-2025-0060251, filed on May 9, 2025, in the Korean Intellectual Property Office, the entire disclosures of which are incorporated herein by reference.

### FIELD

The present disclosure relates to a memory device and more particularly to a memory device including transistors, and to a method of operating the memory device.

### BACKGROUND

Recently, artificial intelligence technology based on artificial neural networks has been utilized in various fields such as image recognition and natural language processing. However, due to the large amount of computation, the existing von Neumann structure has problems such as a data transmission bottleneck between the memory and the computational device, which reduces the computational speed and increases power consumption. To address such issues, compute-in-memory (CIM) technology, which enables computations to be performed directly within the memory, has attracted significant attention.

Various emerging devices such as resistive random access memory (RRAM) and phase change memory (PCM) have been investigated for implementing CIM; however, their low endurance and poor uniformity make commercialization challenging. Static random access memory (SRAM)-based CIM has a simple structure but a large cell size, resulting in low integration, while dynamic random access memory (DRAM)-based 2T1C bit cells have high process difficulty and problems with increasing cell size when implementing multi-levels. Accordingly, there is a growing need for devices that offer higher integration density, simplified fabrication processes, and support for multi-level operation.

### SUMMARY

A memory device according to embodiments comprises an in-memory operation circuit connected to a plurality of write word lines, a plurality of read word lines, and a bit line, and including a plurality of bit cells, each of the plurality of bit cells comprises: a first transistor having one end connected to the bit line, another end connected to a storage node, and a gate connected to a corresponding write word line among the plurality of write word lines, at least one second transistor having one end connected to the bit line, another end connected to a first node, and a gate connected to the storage node, and a selection transistor having one end connected to the first node, another end connected to ground, and a gate connected to a corresponding read word line among the plurality of read word lines; and wherein a turn-on current of the at least one second transistor included in the plurality of bit cells respectively corresponds to a reference current value and a multiplication value of the reference current value and a power of two.

A memory device according to embodiments comprises a plurality of read word lines; a plurality of bit lines; a plurality of bit cells respectively connected to the plurality of bit lines and including storage nodes; and a plurality of selection transistors having gates connected to the plurality of read word lines, one ends connected to first nodes of the plurality of bit cells, and other ends connected to a ground, wherein a selected first bit cell among the plurality of bit cells stores first information corresponding to a digit of first operation target data in the storage node, and when a pulse having a width corresponding to second operation target data is applied to a first read word line connected to a gate of a first selection transistor corresponding to the first bit cell, the first bit cell outputs, to a first bit line corresponding to the first bit cell, a first output current based on a product of the first information, a reference current value, and the second operation target data.

A computing method of a memory device comprising a plurality of bit lines, a plurality of bit cells respectively connected to the plurality of bit lines and including storage nodes, and a plurality of selection transistors connected in series between the plurality of bit cells and a ground node according to embodiments comprises, storing charge in each storage node of a plurality of bit cells by applying a voltage corresponding to first operation target data to a plurality of bit lines, applying a pulse having a width corresponding to second operation target data to a read word line connected to a gate of a selected selection transistor among the plurality of selection transistors, and sensing an operation result based on a first output current output from a first bit line selected from among the plurality of bit lines.

### BRIEF DESCRIPTION OF THE DRAWINGS

FIG. 1 is a block diagram illustrating a semiconductor system according to embodiments.

FIG. 2 is a circuit diagram showing a bit cell according to embodiments.

FIG. 3 is a circuit diagram showing a bit cell according to embodiments.

FIG. 4 is a circuit diagram showing a bit cell according to embodiments.

FIG. 5 is a circuit diagram showing a bit cell according to embodiments.

FIG. 6 is a circuit diagram illustrating the structure of an in-memory multiplier according to embodiments.

FIG. 7 is a circuit diagram illustrating the structure of an in-memory multiplier according to embodiments.

FIG. 8 is a diagram showing the writing operation of the in-memory multiplier according to FIG. 6.

FIG. 9 is a diagram showing the writing operation of the in-memory multiplier according to FIG. 6.

FIG. 10 is a diagram illustrating an in-memory multiplier according to embodiments.

FIG. 11 is a diagram illustrating a sensing circuit according to embodiments.

FIG. 12 is a diagram illustrating a voltage analog-to-digital converter ADC according to FIG. 11.

FIG. 13 is a diagram illustrating a sensing circuit according to embodiments.

FIG. 14 is a diagram for explaining the multiplication operation of the in-memory multiplier according to FIG. 10.

FIG. 15 is a diagram showing the multiplication operation of the in-memory multiplier according to FIG. 10.

### DETAILED DESCRIPTION

Below, with reference to the attached drawings, embodiments of the present disclosure is described in detail so that a person having ordinary skill in the art to which the present disclosure pertains may easily practice it. However, the present disclosure may be implemented in many different forms and is not limited to the embodiments described herein.

And in order to clearly explain the present disclosure in the drawings, parts unrelated to the explanation are omitted, and similar parts are given similar reference numerals throughout the specification. In the flowchart described with reference to the drawing, the order of operations may be changed, several operations may be combined, some operations may be divided, and certain operations may be omitted.

In addition, unless explicitly described otherwise using terms such as “one” or “single,” expressions written in the singular form may be interpreted as including the plural form. Terms that include ordinal numbers such as first and second may be used to distinguish between various elements, but the elements are not limited by such terms. These terms may be used merely to differentiate one element from another.

A memory device and an operation method thereof according to embodiments are for performing internal computational operations in parallel using an in-memory multiplier.

A memory device and an operation method thereof according to embodiments are for performing high-speed, low-power operations using an in-memory multiplier.

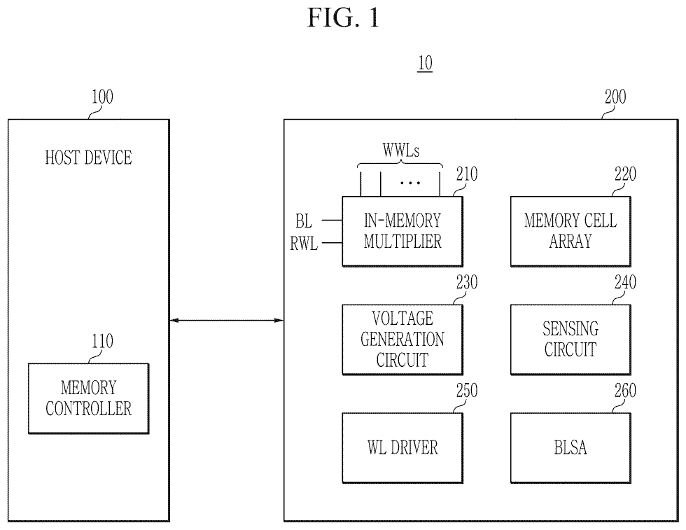

FIG. 1 is a block diagram illustrating a semiconductor system according to embodiments.

Referring to FIG. 1, a semiconductor system 10 according to embodiments of the present disclosure may include a host device 100 and a memory device 200.

The host device 100 may be, for example, a computing system such as a computer, a laptop, a server, a workstation, a portable communication terminal, a PDA (Personal Digital Assistant), a PMP (Portable Multimedia Player), a smart phone, or a wearable device. The host device 100 may be one of the components included in a computing system, such as a graphics card.

The host device 100 is a functional block that performs general computer operations within a semiconductor system 10, and may include a central processing unit (CPU), a digital signal processor (DSP), a graphics processing unit (GPU), or an application processor (AP). The host device 100 may include a memory controller 110 that manages data transmission and reception with the memory device 200.

The memory controller 110 may access the memory device 200 according to a memory request from the host device 100. For example, a memory controller 110 may provide addresses, commands, and data to a memory device 200. The memory controller 110 may access an in-memory multiplier (IMM) 210 included in the memory device 200. The memory controller 110 may control a write operation, a multiplication operation, a refresh operation, or a read operation for the IMM 210. In this specification, an in-memory multiplier IMM 210 may be referred to as an in-memory operation circuit.

In some embodiments, the memory controller 110 may access a memory cell array 220 included in the memory device 200.

The memory device 200 may write data or read data under the control of the memory controller 110. For example, the memory device 200 may be a DDR SDRAM (Double Data Rate Synchronous Dynamic Random Access Memory) device. However, the present disclosure is not limited thereto, and the memory device 200 may be any one of volatile memory devices such as LPDDR (Low Power Double Data Rate) SDRAM, Wide I/O DRAM, HBM (High Bandwidth Memory), HMC (Hybrid Memory Cube), etc. In some embodiments, the memory device 200 may be any one of non-volatile memory devices such as flash memory, phase-change RAM (PRAM), magnetic RAM (MRAM), resistive RAM (RRAM), ferroelectric RAM (FRAM), and the like.

The memory device 200 may be a Compute-In-Memory CIM device or a Processing-In-Memory (PIM) device that performs internal operations under the control of the host device 100.

The memory device 200 may include an IMM 210, a memory cell array 220, a voltage generation circuit 230, a sensing circuit 240, a word line driver 250, and a bit line sense amplifier BLSA 260.

The memory device 200 may operate in processing mode or normal mode. When operating in processing mode, the memory device 200 may perform a write operation, a read operation, a refresh operation, or a multiplication operation on operation target data received from the memory controller 110. When operating in normal mode, the memory device 200 may store data received from the memory controller 110 or provide data requested by the memory controller 110.

IMM 210 may receive operation target data from the memory controller 110. IMM 210 may perform an operation on the operation target data. IMM 210 may perform a write operation, a read operation, a refresh operation, or a multiplication operation on the operation target data. The IMM 210 may be connected to a plurality of write word lines WWLs, bit lines BL, and read word lines RWL.

The memory cell array 220 may store data provided from the memory controller 110 or provide data requested by the memory controller 110. The memory cell array 220 may be connected to bit lines and word lines. The memory cell array 220 may operate in normal mode.

The memory controller 110 may access the IMM 210 or the memory cell array 220 through an address. However, the present disclosure is not limited thereto, and the IMM 210 may be included in a memory cell array 220, and a part of the memory cell array 220 may operate as the IMM 210.

Each of the IMM 210 and the memory cell array 220 may include a plurality of memory cells. The IMM 210 may include a 2T0C (2-Transistor, 0-Capacitor) cell and a selection transistor. The memory cells included in the IMM 210 may be referred to as bit cells. For example, a bit cell may include oxide transistors. A multiplication operation may be performed on data stored in a bit cell. The selection transistor may control the flow of current output from each bit cell.

The memory cell array 220 may include 2T0C (2-Transistor, 0-Capacitor) cells or 2T1C (2-Transistor, 1-Capacitor) cells.

The voltage generation circuit 230 may generate voltages applied to a plurality of write word lines WWLs, bit lines BL, and read word lines RWL.

The sensing circuit 240 may detect the current or voltage output from the bit line BL. For example, the sensing circuit 240 may detect the current value of the current output from the bit line BL, and obtain data stored in the IMM 210 or data corresponding to the result of a multiplication operation by the IMM 210 based on the detected current value. For example, the sensing circuit 240 may detect the voltage value of a node connected to a bit line BL, and obtain data stored in the IMM 210 or data corresponding to the result of a multiplication operation by the IMM 210 based on the detected voltage value.

The word line driver 250 may apply the voltage generated by the voltage generation circuit 230 to the write word line WWL or the read word line RWL.

The bit line sense amplifier 260 may apply the voltage generated by the voltage generation circuit 230 to the bit line BL.

When the memory device 10 operates in processing mode, during a write operation, the IMM 210 may store first operation target data in a plurality of bit cells included in the IMM 210 based on voltages provided from a plurality of bit lines BLs. For example, when a first write bit line voltage (e.g., a high-level voltage) is applied to the bit line BL, ‘1’ may be stored in the bit cell, and when a second write bit line voltage (e.g., a low-level voltage) is applied to the bit line BL, ‘0’ may be stored in the bit cell.

During a multiplication operation, the IMM 210 may perform a multiplication operation on the first operation target data and the second operation target data based on a voltage corresponding to the first operation target data stored in a plurality of bit cells and the second operation target data provided through a read word line RWL via a voltage generation circuit 230.

During a read operation, the IMM 210 may selectively turn on read transistors within a plurality of bit cells according to the first operation target data, and output the sum of turn-on currents output by the plurality of bit cells to a bit line BL by turning on the selection transistor. The sensing circuit 240 may obtain first operation target data corresponding to the read result based on the sum of the turn-on currents. A read operation may be an example of a multiplication operation. Specifically, the multiplication operation when the second operation target data is ‘1’ may be a read operation.

During a refresh operation, the memory device 200 may maintain the first operation target data stored in the plurality of bit cells in the storage nodes within the plurality of bit cells. For example, the storage node may be the gate node of a corresponding read transistor. In embodiments, the memory device 200 may include a plurality of bit line sense amplifiers 260 connected to bit lines BL, and may perform a refresh operation based on the plurality of bit line sense amplifiers 260.

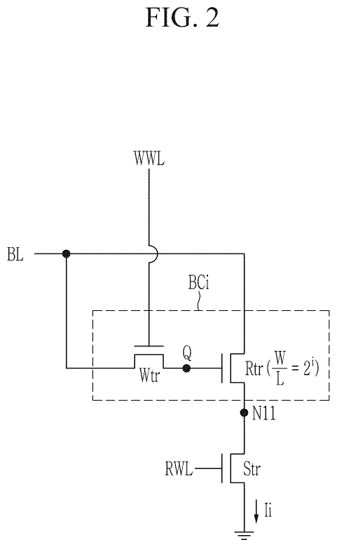

FIG. 2 is a circuit diagram showing a bit cell according to embodiments.

The bit cell BCi may store the first operation target data. Referring to FIG. 2, the bit corresponding to the ith digit of the first operation target data may be stored in the storage node Q of the ith bit cell BCi. The storage node Q does not have a separate external terminal and may store charges transferred from the bit line BL by the turn-on operation of the write transistor Wtr or may release charges toward the bit line BL through the read transistor Rtr.

In embodiments, the bit cell BCi may have a 2T0C structure. For example, a bit cell BCi may include a write transistor Wtr and a read transistor Rtr. The write transistor Wtr may include one or more oxide semiconductors as a channel material among indium gallium zinc oxide InGaZnO; IGZO, indium oxide In₂O₃, indium tungsten oxide IWO, indium gallium oxide IGO, indium tin oxide ITO, indium gallium zinc tin oxide IGZTO, indium tin zinc oxide ITZO, indium zinc tin oxide IZTO, aluminum zinc oxide AZO, and indium aluminum zinc oxide IAZO. However, the present disclosure is not limited thereto, and the channels of the write transistor Wtr and the read transistor Rtr may include various materials.

One end of the write transistor Wtr may be connected to a bit line BL, the other end of the write transistor Wtr may be connected to a storage node Q, and the gate may be connected to a write word line WWL.

One end of the read transistor Rtr may be connected to a bit line BL, the other end may be connected to a first node N11, and the gate may be connected to a storage node Q.

A selection transistor Str may be connected to the first node N11 of the bit cell BCi. The selection transistor Str may be connected in series between the read transistor Rtr and ground. One end of the selection transistor Str may be connected to the first node N11, the other end of the selection transistor Str may be connected to the ground GND, and the gate may be connected to the read word line RWL.

When a write operation is performed, the bit corresponding to the ith digit of the first operation target data may be stored in the storage node Q. If the first operation target data includes N bits (N is a natural number), the bit corresponding to the 0th digit may be the LSB, and the bit corresponding to the N−1th digit may be the MSB. For example, during a write operation, a turn-on voltage VPP≥VDD+VTH is applied to the write transistor Wtr through the write word line WWL, so that the write transistor Wtr is turned on, and while the turn-on voltage is applied to the write word line WWL, a voltage at a level indicating ‘1’ or a voltage at a level indicating ‘0’ may be applied to the bit line BL. Accordingly, ‘1’ or ‘0’ may be stored in the storage node Q.

In the case of a selected bit cell BCi during a read operation, a turn-on voltage is applied to the selection transistor Str through the read word line RWL, so that the selection transistor Str is turned on and the bit cell BCi may be activated. The bit cell BCi may provide a turn-on current Ii having a current value corresponding to the multiplication value of the digit value of the ith digit of the first operation target data and the reference current value in the direction of the bit line BL through the selection transistor Str. In embodiments, the bit line BL may be connected to the sensing circuit 240 (FIG. 1).

Meanwhile, during a read operation, a turn-off voltage is applied to the selection transistor of an unselected bit cell through the read word line RWL, so that the selection transistor Str is turned off, and the bit cell may be deactivated.

During a multiplication operation, the second operation target data may be provided through a read word line RWL. During a multiplication operation, the bit cell BCi may provide a turn-on current Ii having a current value corresponding to the multiplication value of the digit value of the ith digit of the first operation target data, the reference current value, and the second operation target data in the direction of the bit line BL. For example, when ‘1’ is stored in the storage node Q and a pulse having a width T is applied through the read word line RWL, the selection transistor Str may turned on and may provide a current proportional to the product of 2\hat{ }i, the reference current value, and the pulse width T to the bit line BL.

In FIG. 2, the channel width-to-length ratio W/L ratio of the read transistor Rtr may correspond to the multiplication value of the reference channel width-to-length ratio and a power of 2. For example, the channel width-to-length ratio of the read transistor Rtr may correspond to 2ⁱ. Specifically, the channel width-to-length ratio W/L ratio of the read transistor Rtr may correspond to the multiplication value of the reference channel width-to-length ratio and 2ⁱ.

For example, the channel width-to-length ratio of the read transistor included in the first bit cell among the plurality of bit cells may correspond to a multiplication value of the reference channel width-to-length ratio and 2⁰, the channel width-to-length ratio of the read transistor included in the second bit cell may correspond to a multiplication value of the reference channel width-to-length ratio and 2¹, the channel width-to-length ratio of the read transistor included in the third bit cell may correspond to a multiplication value of the reference channel width-to-length ratio and 2², and the channel width-to-length ratio of the read transistor included in the fourth bit cell may correspond to a multiplication value of the reference channel width-to-length ratio and 2³. The reference channel width-to-length ratio may refer to the channel width-to-length ratio of a read transistor included in the first bit cell.

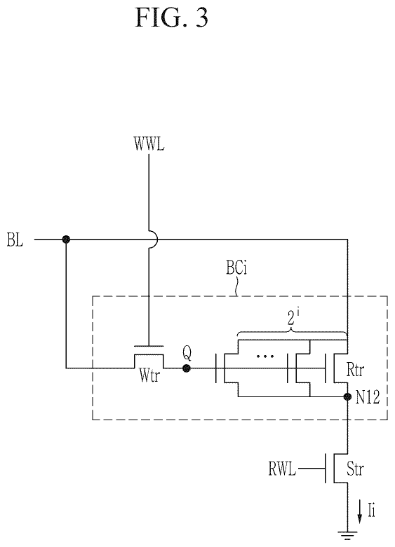

FIG. 3 is a circuit diagram showing a bit cell according to embodiments.

In FIG. 3, a bit cell BCi may include 2ⁱ read transistors Rtr.

In FIG. 3, one end of 2ⁱ read transistors Rtr may be commonly connected to a bit line BL, the other ends may be commonly connected to a first node N12, and the gates may be commonly connected to a storage node Q. That is, in FIG. 3, 2ⁱ read transistors Rtr may be connected in parallel between the read bit line RBL and the first node N12.

The selection transistor Str may be connected between the first node N12 and ground. The selection transistor Str may be connected in series between the read transistor Rtr and ground. One end of the selection transistor Str may be connected to the first node N12, the other end of the selection transistor Str may be connected to the ground GND, and the gate may be connected to the read word line RWL.

In FIG. 3, the channel width-to-length ratios of the 2ⁱ read transistors Rtr may be the same. Therefore, the current values of the turn-on currents of the 2ⁱ read transistors Rtr may be the same.

When a write operation is performed, the bit corresponding to the ith digit of the first operation target data may be stored in the storage node Q. If the first operation target data includes N bits (N is a natural number), the bit corresponding to the 0th digit may be the LSB, and the bit corresponding to the N−1th digit may be the MSB.

During a read operation, the sum of the current values of the turn-on currents provided by 2ⁱ read transistors Rtr to the read bit line RBL may correspond to the multiplication value of the reference current value and 2ⁱ.

During a read operation, in the case of a selected bit cell BCi during a read operation, a turn-on voltage is applied to the selection transistor Str through the read word line RWL, so that the selection transistor Str is turned on and the bit cell BCi may be activated. The bit cell BCi may provide a turn-on current Ii having a current value corresponding to the multiplication value of the digit value of the i-th digit of the first operation target data and the reference current value in the direction of the bit line BL through the selection transistor Str. In embodiments, the bit line RBL may be connected to the sensing circuit 240 (FIG. 1).

Meanwhile, during a read operation, a turn-off voltage is applied to the selection transistor of an unselected bit cell through the read word line RWL, so that the selection transistor Str is turned off, and the bit cell may be deactivated.

During a read operation, the bit cell BCi may provide a current having a current value corresponding to a multiplication value of 2ⁱ, which is the place value of the bit located at the i-th digit of the first operation target data, and a reference current value, to the bit line BL.

During a multiplication operation, the second operation target data may be provided through a read word line RWL. During a multiplication operation, the bit cell BCi may provide a turn-on current Ii having a current value corresponding to the multiplication value of the digit value of the i-th digit of the first operation target data, the reference current value, and the second operation target data in the direction of the bit line BL while the selection transistor Str is turned on. For example, when ‘1’ is stored in the storage node Q and a pulse having a width T is applied through the read word line RWL, the selection transistor Str may provide a current proportional to the product of 2\hat{ }i, the reference current value, and the pulse width T to the bit line BL.

During a multiplication operation, the sum of the current values of the turn-on currents provided by 2ⁱ read transistors Rtr to the bit line BL may correspond to a multiplication value of the reference current value, 2ⁱ, and the second operation target data.

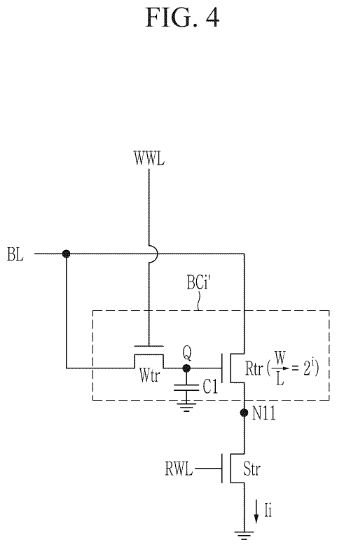

FIG. 4 is a circuit diagram showing a bit cell according to embodiments.

In embodiments, the bit cell BCi′ may have a 2T1C structure. For example, the bit cell BCi′ may further include a capacitor C1. One end of the capacitor C1 may be connected to the storage node Q, and the other end may be connected to the ground node. By connecting the capacitor C1 to the storage node Q, the amount of charge stored in the storage node Q may increase.

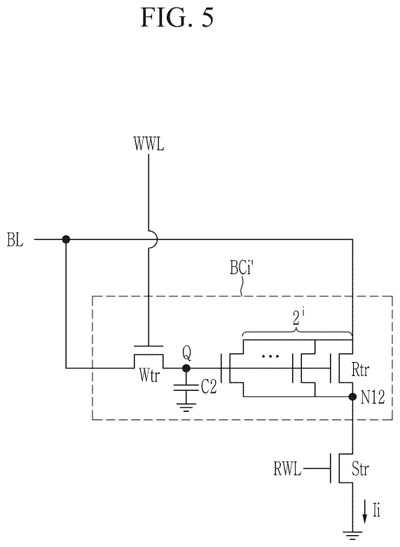

FIG. 5 is a circuit diagram showing a bit cell according to embodiments.

In embodiments, the bit cell BCi′ may have a 2T1C structure. For example, the bit cell BCi′ may further include a capacitor C2. One end of the capacitor C2 may be connected to the storage node Q, and the other end may be connected to the ground node. By connecting the capacitor C2 to the storage node Q, the amount of charge stored in the storage node Q may increase.

Hereinafter, the bit cell included in the IMM 210 (FIG. 1) is described as being the bit cell BCi of FIG. 2 or FIG. 3, but the embodiments are not limited thereto. The bit cell included in the IMM 210 may be the bit cell BCi′ of FIG. 4 or FIG. 5, but is not limited thereto and may have various structures including the write transistor Wtr and the read transistor Rtr of the bit cell BCi of FIGS. 2 and 3.

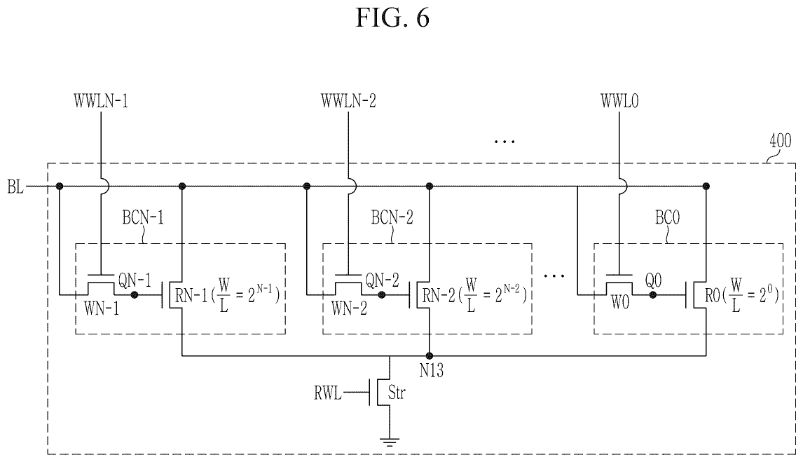

FIG. 6 is a circuit diagram illustrating the structure of an in-memory multiplier according to embodiments.

Referring to FIG. 6, an IMM 400 according to embodiments may include first to N bit cells BC0-BCN−1.

Each of the first to N-bit cells BC0-BCN−1 may include a corresponding write transistor among a plurality of write transistors W0-WN−1, a corresponding read transistor among a plurality of read transistors R0-RN−1, and a selection transistor Str.

The gates of the plurality of write transistors W0-WN−1 may be connected to a write word line WWL. One end of each of the plurality of write transistors W0-WN−1 may be connected to a bit line BL. For example, one end of the write transistor W0, the write transistor WN−2, and the write transistor WN−1 may be connected to the bit line BL. The other end of each of the write transistors W0-WN−1 may be connected to a corresponding storage node. For example, the other end of the write transistor W0 may be connected to the storage node Q0, the other end of the write transistor WN−2 may be connected to the storage node QN−2, and the other end of the write transistor WN−1 may be connected to the storage node QN−1.

One end of the plurality of read transistors R0-RN−1 may be connected to a bit line BL. The other end of the plurality of read transistors R0-RN−1 may be connected to the first node N13. The gate of each of the plurality of read transistors R0-RN−1 may be connected to a corresponding storage node. For example, the gate of the read transistor R0 may be connected to the storage node Q0, the gate of the read transistor RN−2 may be connected to the storage node QN−2, and the gate of the read transistor RN−1 may be connected to the storage node QN−1.

The channel width-to-length ratio W/L of the plurality of read transistors R0-RN−1 may correspond to the multiplication value of the reference channel width-to-length ratio and a power of 2. For example, the channel width-to-length ratio of the read transistor R0 may be a product of the reference channel width-to-length ratio and 2°, the channel width-to-length ratio of the read transistor RN−2 may be a product of the reference channel width-to-length ratio and 2N−2, and the channel width-to-length ratio of the read transistor RN−1 may be a product of the reference channel width-to-length ratio and 2N−1. The reference channel width-to-length ratio may refer to the channel width-to-length ratio of the read transistor R0.

One end of the selection transistor Str may be connected to the first node N13, and the other end may be connected to ground GND.

During a write operation, first operation target data may be stored in storage nodes Q0-QN−1 of first to N bit cells BC0-BCN−1 based on the voltage provided through the bit line BL. For example, when a first bit line voltage (e.g., a high level voltage) is applied to the bit line BL, ‘1’ may be stored in the storage node Q0, and when a second write bit line voltage (e.g., a low level voltage) is applied to the bit line BL, ‘0’ may be stored in the storage node Q0. For example, the first write bit line voltage may be a positive power supply voltage VDD, and the second write bit line voltage may be a ground GND.

During a read operation, each of the read transistors R0-RN−1 may output a turn-on current having a size proportional to the corresponding channel width-to-length ratio while the selection transistor Str is turned on. That is, each of the read transistors R0-RN−1 may provide a turn-on current having a current value corresponding to the multiplication value of the digit value of the corresponding digit and the reference current value to the bit line BL. Accordingly, the total current for the turn-on currents provided to the bit line BL through the selection transistor Str may have a current value corresponding to the multiplication value of the first operation target data and the reference current value. In embodiments, the bit line BL may be connected to the sensing circuit 240 (FIG. 1).

During a multiplication operation, the word line driver 250 (FIG. 1) may provide a pulse having a width corresponding to the second operation target data to a plurality of write word lines WWL0-WWLN−1. Each of the read transistors R0-RN−1 may provide a turn-on current having a size proportional to the corresponding channel width-to-length ratio and the second operation target data to the bit line BL while the selection transistor Str is turned on. That is, each of the read transistors R0-RN−1 may provide a turn-on current value corresponding to a multiplication value of the digit value corresponding to the first operation data, a reference current value, and the second operation target data to the bit line BL. Therefore, the total current for the turn-on currents provided to the bit line BL may have a current value corresponding to the multiplication value of the first operation target data, the reference current value, and the second operation target data.

The sensing circuit 240 may obtain first operation target data corresponding to the result of the read operation or binary data corresponding to the result of the multiplication operation based on the total current.

A memory device 200 (FIG. 1) according to embodiments of the present disclosure may operate as a Compute-In-Memory CIM by performing a multiplication operation using bit cells whose turn-on currents have ratios equal to power of 2.

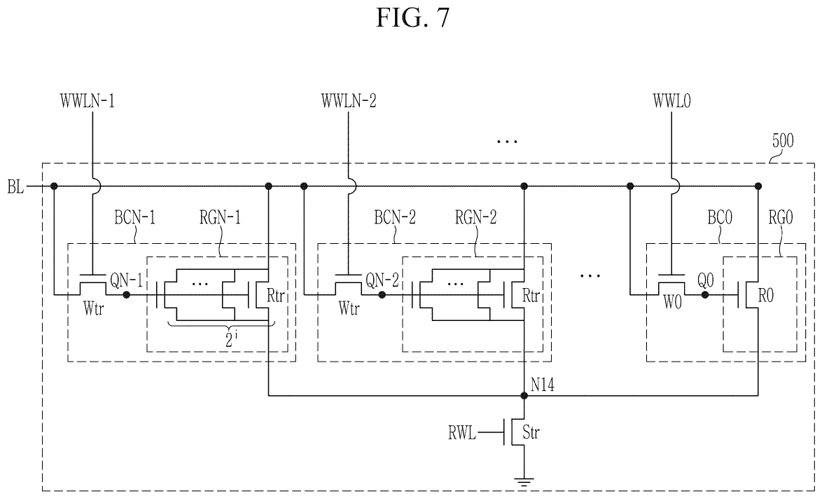

FIG. 7 is a circuit diagram illustrating the structure of an in-memory multiplier according to embodiments.

Referring to FIG. 7, an IMM 500 according to embodiments may include first to N bit cells BC0 to BCN−1.

The first to N-bit cells BC0-BCN−1 may include a plurality of read transistors Rtr in a number corresponding to a power of 2. Additionally, the first to N-bit cells BC0-BCN−1 may include different numbers of read transistors Rtr. The number of read transistors Rtr may be equal to the digit value of the digit corresponding to the first to Nth bit cells BC0-BCN−1. For example, the first bit cell BC0 may include 2⁰ read transistors Rtr corresponding to the 0th digit value, the N−1th bit cell BCN−2 may include 2N−2 read transistors Rtr corresponding to the N−2th digit value, and the Nth bit cell BCN−1 may include 2N−1 read transistors Rtr corresponding to the N−1th digit value.

In each of the first to Nth bit cells BC0-BCN−1, one end of a plurality of read transistors Rtr may be connected to a bit line BL, and the other end of the plurality of read transistors Rtr may be connected to a first node N14.

A set of read transistors Rtr included in each of the first to Nth bit cells BC0-BCN−1 may be referred to as a read transistor group. For example, one read transistor included in a first bit cell BC0 may be referred to as a first read transistor group RG0, 2^{N-2} read transistors Rtr included in an N−1-th bit cell BCN−2 may be referred to as an N−1-th read transistor group RGN−2, and 2N−1 read transistors Rtr included in an N-th bit cell BCN−1 may be referred to as an N-th read transistor group RGN−1. The gates of the plurality of read transistors Rtr within one read transistor group may be connected to corresponding storage nodes.

One end of the selection transistor Str is connected to the first node N14, the other end is connected to ground GND, and the gate may be connected to a read word line RWL.

During a read operation, each of the first to Nth read transistor groups RG0 to RGN−1 may output a turn-on current having a current value proportional to the number of read transistors included in each of the first to Nth read transistor groups RG0 to RGN−1 to the read bit line RBL. That is, each of the first to Nth read transistor groups RG0 to RGN−1 may provide a turn-on current having a current value corresponding to a multiplication value of the digit value of the digit corresponding to each of the first to Nth read transistor groups RG0 to RGN−1 and the reference current value to the bit line BL. Therefore, the total current for the turn-on currents provided to the bit line BL may have a current value corresponding to the multiplication value of the first operation target data and the reference current value.

During a multiplication operation, each of the first to Nth read transistor groups RG0 to RGN−1 may output a turn-on current having a size proportional to the number of read transistors included in each of the first to Nth read transistor groups RG0 to RGN−1 and the second operation target data to the bit line BL. That is, each of the first to Nth read transistor groups RG0 to RGN−1 may provide a turn-on current having a current value corresponding to a multiplication value of the digit value of the digit corresponding to each of the first to Nth read transistor groups RG0 to RGN−1, the reference current value, and the second operation target data to the bit line BL. Therefore, the total current for the turn-on currents provided to the bit line BL may have a current value corresponding to the multiplication value of the first operation target data, the reference current value, and the second operation target data.

Hereinafter, the description may be made with particular reference to the IMM 400 of FIG. 6. However, the description of the IMM 400 of FIG. 6 may also be applied to the IMM 500 of FIG. 7. For example, the turn-on current provided by the read transistor (Ri, i is an integer from 0 to N−1) among the read transistors R0-RN−1 of FIG. 6 to the bit line BL may be the same as the turn-on current provided by the read transistor group RGi among the read transistor groups RG0-RGN−1 of FIG. 7 to the bit line BL.

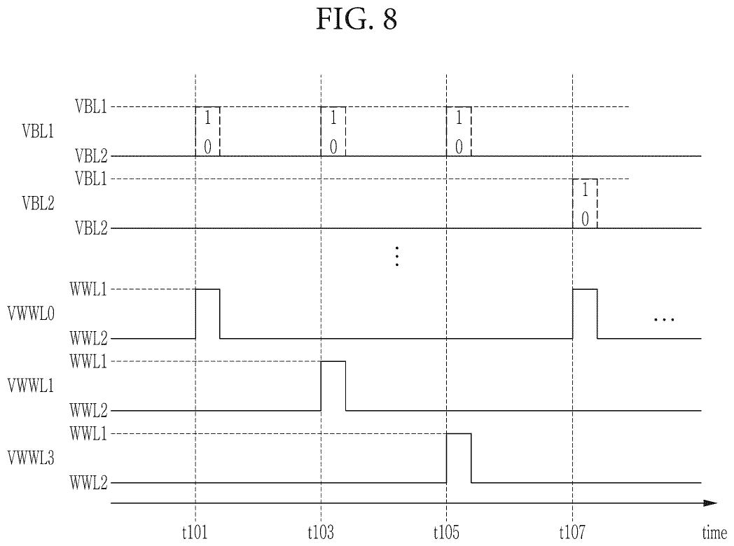

FIG. 8 is a diagram showing the writing operation of the in-memory multiplier according to FIG. 6.

Specifically, FIG. 8 is a diagram illustrating an operation of storing multi-bit information in the plurality of bit cells BC0-BCN−1 of an IMM 400 (FIG. 6).

First, the bit line BL is initialized through the bit line sense amplifier 260 (FIG. 1).

At the first time point t101, the bit line sense amplifier 260 may apply a first bit line voltage VBL1 or a second bit line voltage VBL2 to the first bit line BL1. The first bit line voltage VBL1 may be a power supply voltage VDD. The second bit line voltage VBL2 may be a ground GND.

At this time, the word line driver 250 (FIG. 1) may apply the first write word line voltage VWWL1 to the first write word line WWL0. The first write word line voltage VWWL1 may be a turn-on voltage Vpp. Here, it may be desirable for the turn-on voltage be equal to or greater than a voltage that exceeds a supply voltage VDD by at least a threshold voltage VTH of a write transistor W0, that is, VPP≥VDD+VTH.

While the first write word line voltage VWWL0 is applied, the write transistor W0 is turned on, and a precharged first bit-line voltage VBL1 or second bit-line voltage VBL2 applied to one end of the write transistor W0 may be transferred to the other end of the write transistor W0. Accordingly, bit information corresponding to the storage node Q0 of the bit cell BC0 may be stored.

After a predetermined time has elapsed, the word line driver 250 may apply a second write word line voltage VWWL2 to the first write word line WWL0. The second write word line voltage VWWL2 may be a ground GND. Accordingly, the write transistor W0 is turned off, and the voltage applied to the storage node Q0 may be maintained. At this time, since the write transistor W0 uses an oxide semiconductor as a channel material, the leakage current in the turn-off state is extremely small, so the charge stored in the storage node Q0 may be preserved for a long period of time.

At the second time point t103, the bit line sense amplifier 260 may apply a first bit line voltage VBL1 or a second bit line voltage VBL2 to the first bit line BL1.

At this time, the word line driver 250 may apply the first write word line voltage VWWL1 to the second write word line WWL1. The first write word line voltage VWWL1 may be a turn-on voltage Vpp.

While the first write word line voltage VWWL1 is applied, the write transistor W1 is turned on, and bit information corresponding to the storage node Q1 of the bit cell BC1 may be stored.

After a predetermined time has elapsed, the word line driver 250 may apply a second write word line voltage VWWL2 to the second write word line WWL1. The second write word line voltage VWWL2 may be a ground GND. Accordingly, the write transistor W1 is turned off, and the voltage applied to the storage node Q1 may be maintained.

At the third time point t105, the bit line sense amplifier 260 may apply a first bit line voltage VBL1 or a second bit line voltage VBL2 to the first bit line BL1.

At this time, the word line driver 250 may apply the first write word line voltage VWWL1 to the N−1 write word line WWLN−1. The first write word line voltage VWWL1 may be a turn-on voltage Vpp.

While the first write word line voltage VWWL1 is applied, the write transistor WN−1 is turned on, and bit information corresponding to the storage node QN−1 of the bit cell BCN−1 may be stored.

After a predetermined time has elapsed, the word line driver 250 may apply a second write word line voltage VWWL2 to the N−1 write word line WWLN−1. The second write word line voltage VWWL2 may be a ground GND. Accordingly, the write transistor WN−1 is turned off, and the voltage applied to the storage node QN−1 may be maintained.

Specifically, when the bit line is precharged by the first bit line voltage VBL1, ‘1’ may be stored in the corresponding storage node Q, and when the bit line is precharged by the second bit line voltage VBL2, ‘0’ may be stored in the corresponding storage node Q. However, the present disclosure is not limited thereto, and ‘0’ may be stored in a storage node Q precharged by a first bit line voltage VBL1, and ‘1’ may be stored in a storage node Q precharged by a second bit line voltage VBL2.

In FIG. 8, the first bit line voltage VBL1 is shown to be higher than the level of the second bit line voltage VBL2, but the present disclosure is not limited thereto. For example, if the write transistors W0 to WN−1 are P-type transistors, unlike the write transistors W0 to WN−1 illustrated as N-type transistors in FIG. 6, the first bit line voltage VBL1 may be lower than the level of the second bit line voltage VBL2.

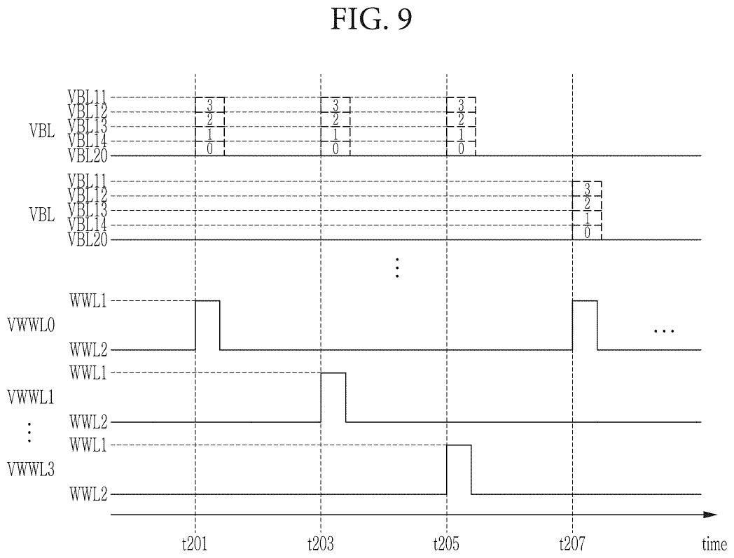

FIG. 9 is a diagram showing the writing operation of the in-memory multiplier according to FIG. 6.

Specifically, FIG. 9 is a diagram illustrating an operation of storing multi-level information in each of a plurality of bit cells BC0-BCN−1 of an IMM 400 (FIG. 6).

For example, in embodiments, a write operation of the IMM 400 may include sequentially inputting binary information through a plurality of write bit lines WBL0-WBLN−1 and storing the data in corresponding storage nodes Q0-QN−1 of a plurality of bit cells BC0-BCN−1 by controlling write transistors WN0-WN−1 through write word lines WWL. While the IMM 400 performs a write operation, the selection transistor Str may be kept in an off state to block the output path.

First, the bit line BL is initialized through the bit line sense amplifier 260.

At a first time point t201, the bit line sense amplifier 260 (FIG. 1) may apply a first bit line voltage VBL11, a second bit line voltage VBL12, a third bit line voltage VBL13, or a fourth bit line voltage VBL20 to the first bit line BL1. The first bit line voltage VBL1 may be a power supply voltage VDD. The fourth bit line voltage VBL2 may be a ground GND.

At this time, the word line driver 250 (FIG. 1) may apply the first write word line voltage VWWL1 to the first write word line WWL0. The first write word line voltage VWWL1 may be a turn-on voltage Vpp. Here, it may be desirable for the turn-on voltage to be a voltage greater than a supply voltage VDD by at least a threshold voltage VTH of the write transistor W0, that is, VPP≥VDD+VTH.

While the first write word line voltage VWWL0 is applied, the write transistor W0 is turned on, and the first bit line voltage VBL1 or the second bit line voltage VBL2 precharged at one end of the write transistor W0 may be transferred to the other end of the write transistor W0. Accordingly, bit information corresponding to the storage node Q0 of the bit cell BC0 may be stored.

After a predetermined time has elapsed, the word line driver 250 may apply a second write word line voltage VWWL2 to the first write word line WWL0. The second write word line voltage VWWL2 may be a ground GND. Accordingly, the write transistor W0 is turned off, and the voltage applied to the storage node Q0 may be maintained. At this time, since the write transistor W0 uses an oxide semiconductor as a channel material, the leakage current in the turn-off state is extremely small, so the charge stored in the storage node Q0 may be preserved for a long period of time.

At the second time point t203, the bit line sense amplifier 260 may apply a first bit line voltage VBL11, a second bit line voltage VBL12, a third bit line voltage VBL13, or a fourth bit line voltage VBL20 to the first bit line BL1. The first bit line voltage VBL1 may be a power supply voltage VDD. The fourth bit line voltage VBL2 may be a ground GND.

At this time, the word line driver 250 may apply the first write word line voltage VWWL1 to the second write word line WWL1. The first write word line voltage VWWL1 may be a turn-on voltage Vpp.

While the first write word line voltage VWWL1 is applied, the write transistor W1 is turned on, and bit information corresponding to the storage node Q1 of the bit cell BC1 may be stored. For example, a bit of information may contain two bits of information.

After a predetermined time has elapsed, the word line driver 250 may apply a second write word line voltage VWWL2 to the second write word line WWL1. The second write word line voltage VWWL2 may be a ground GND. Accordingly, the write transistor W1 is turned off, and the voltage applied to the storage node Q1 may be maintained.

At a third time point t205, the bit line sense amplifier 260 may apply a first bit line voltage VBL11, a second bit line voltage VBL12, a third bit line voltage VBL13, or a fourth bit line voltage VBL20 to the first bit line BL1. The first bit line voltage VBL1 may be a power supply voltage VDD. The fourth bit line voltage VBL2 may be a ground GND.

At this time, the word line driver 250 may apply the first write word line voltage VWWL1 to the N−1 write word line WWLN−1. The first write word line voltage VWWL1 may be a turn-on voltage Vpp.

While the first write word line voltage VWWL1 is applied, the write transistor WN−1 is turned on, and bit information corresponding to the storage node QN−1 of the bit cell BCN−1 may be stored. For example, a bit of information may contain two bits of information.

After a predetermined time has elapsed, the word line driver 250 may apply a second write word line voltage VWWL2 to the N−1 write word line WWLN−1. The second write word line voltage VWWL2 may be a ground GND. Accordingly, the write transistor WN−1 is turned off, and the voltage applied to the storage node QN−1 may be maintained.

Specifically, when precharged by the first bit line voltage VBL1, ‘1’ may be stored in the corresponding storage node Q, and when precharged by the second bit line voltage VBL2, ‘0’ may be stored in the corresponding storage node Q. However, the present disclosure is not limited thereto, and ‘0’ may be stored in a storage node Q precharged by a first bit line voltage VBL1, and ‘1’ may be stored in a storage node Q precharged by a second bit line voltage VBL2.

In FIG. 8, the first bit line voltage VBL1 is shown to be higher than the level of the second bit line voltage VBL2, but the present disclosure is not limited thereto. For example, if the write transistors W0 to WN−1 are P-type transistors, unlike the write transistors W0 to WN−1 illustrated as N-type transistors in FIG. 6, the first bit line voltage VBL1 may be lower than the level of the second bit line voltage VBL2.

By applying a multi-level voltage to the storage node Q of the bit cell, more than two bits of data may be stored, which has the effect of reducing the number of bit cells required to implement the same operational range. Accordingly, more operations may be performed within the same area.

Meanwhile, the present disclosure is not limited thereto, and the bit line sense amplifier 260 may apply a multi-level voltage having at least two levels to the bit line.

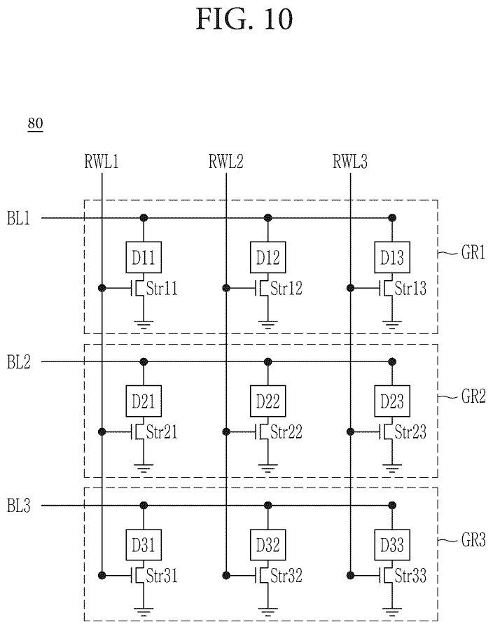

FIG. 10 is a diagram illustrating an in-memory multiplier according to embodiments.

For example, FIG. 10 illustrates an IMM 80 in which a plurality of bit cells are arranged in a matrix structure. In embodiments, the IMM 80 may include a plurality of bit cells Di,j arranged in M rows and N columns, a plurality of read word lines RWL1-RWLn, a plurality of bit lines BL1-BLm, and a plurality of write word lines WWL1-WWLn. For example, a plurality of bit lines BL1-BLm may extend in a first direction and be connected to a plurality of bit cells arranged along the first direction. For example, a plurality of bit lines BL1-BLm may transmit a control signal output from a bit line sense amplifier 260 (FIG. 1) to elements provided in a bit cell Di,j, for example, one end of a write transistor and one end of a read transistor.

A plurality of read word lines RWL1-RWLn extend in a second direction and may be connected to a plurality of bit cells arranged along the second direction. For example, the plurality of read word lines RWL1-RWLn may transmit a control signal output from a word line driver 250 (FIG. 1) to elements provided in a bit cell Di,j, for example, a gate of a selection transistor.

Meanwhile, although not shown in FIG. 8, a plurality of write word lines WWL1 WWLn (FIG. 6) extend in the second direction and may be connected to a plurality of bit cells arranged along the second direction. For example, the plurality of read word lines RWL1-RWLn may transmit a control signal output from a word line driver 250 to elements provided in a bit cell Di,j, for example, a gate of a write transistor.

In FIG. 8, for convenience of explanation, an IMM 80 including a plurality of bit cells (D11, D12, D13, D21, D22, D23, D31, D32, D33) arranged in three rows and three columns is illustrated, but the present disclosure is not limited thereto. In embodiments, each of the plurality of bit cells (D11, D12, D13, D21, D22, D23, D31, D32, D33) may be a bit cell as described with reference to FIGS. 2 through 7.

A bit-cell group GR1, GR2, GR3 may include the plurality of bit cells connected to the same bit line. That is, the plurality of bit cells connected to the same bit line may be grouped into one bit-cell group. For example, a first bit-cell group GR1 corresponding to a first bit line BL1 may include a plurality of bit cells D11, D12, D13 connected to the first bit line BL1. A second bit-cell group GR2 corresponding to a second bit line BL2 may include a plurality of bit cells D21, D22, D23 connected to the second bit line BL2. A third bit-cell group GR3 corresponding to a third bit line BL3 may include a plurality of bit cells D31, D32, D33 connected to the third bit line BL3.

The output currents of the plurality of bit cells constituting each row, i.e., the plurality of bit cells included in one bit-cell group, may be summed according to Kirchhoff's law in a bit line BL or ground wiring.

Each of the plurality of bit cells (D11, D12, D13, D21, D22, D23, D31, D32, D33) may be connected to a corresponding selection transistor (Str11, Str12, Str13, Str21, Str22, Str23, Str31, Str32, Str33). Each of the plurality of selection transistors (Str11, Str12, Str13, Str21, Str22, Str23, Str31, Str32, Str33) may be connected in series between the corresponding bit cell and the ground GND.

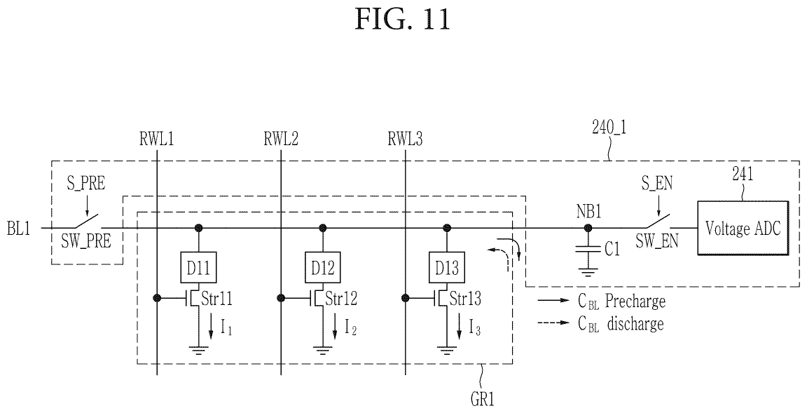

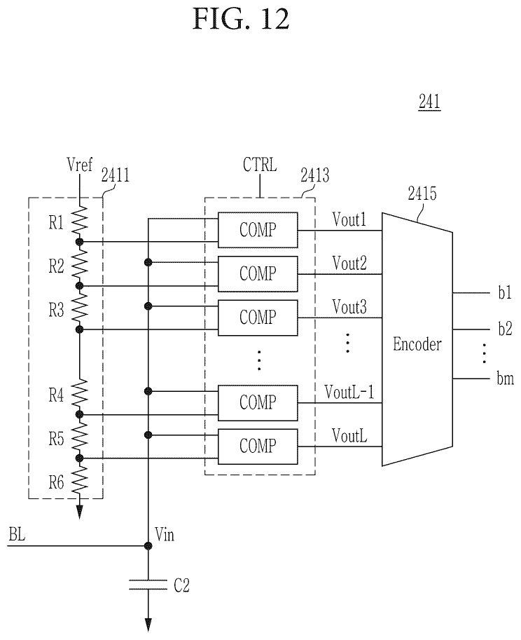

FIG. 11 is a diagram illustrating a sensing circuit according to embodiments. FIG. 12 is a diagram illustrating a voltage analog-to-digital converter (ADC) according to FIG. 11.

Specifically, FIG. 9 illustrates a sensing circuit 240_1 connected to the first bit-cell group GR1. The sensing circuit 240_1 may convert the current output from the first bit-cell group GR1 into a voltage and convert the converted voltage into a digital value.

The sensing circuit 240_1 may include a precharge switch SW_PRE, a first capacitor C1, an enable switch SW_EN, and a voltage ADC 241 connected to a first bit line BL1.

A precharge switch SW_PRE may be connected between the bit line sense amplifier 260 and the first bit-cell group GR1. The precharge switch SW_PRE may be controlled by a first signal S_PRE. For example, the voltage generation circuit 230 may generate a first signal S_PRE of an enable or disable level, and the bit line sense amplifier 260 may output the first signal S_PRE to a precharge switch SW_PRE connected to a corresponding bit line.

A first capacitor C1 may be connected between the first bit line BL1 and a ground GND. As illustrated in FIG. 9, the first capacitor C1 may be connected to the first node NB1.

An enable switch SW_EN may be connected between the first node NB1 and the voltage ADC 241. The enable switch SW_EN may be controlled by a second signal S_EN. For example, the voltage generation circuit 230 may generate a second signal S_EN of an enable or disable level, and the bit line sense amplifier 260 may output the second signal S_EN to an enable switch SW_EN connected to a corresponding bit line.

The voltage ADC 241 may convert the current output from the first bit-cell group GR1 into a voltage and convert the converted voltage into a digital value.

Referring to FIG. 12, the ADC 241 may convert an analog input signal Vin into a digital output signal b1-bm. The analog input signal Vin may be a voltage charged to the second capacitor C2. The second capacitor C2 may be charged by the current provided from the first bit line BL1 of the IMM 80, and the voltage charged during the reference time may be applied to the comparator circuit 2413 as an analog input signal Vin.

The digital output signal b1-bm may be composed of the plurality of bits. During a read operation, the binary number indicated by the digital output signal b1-bm may be the first operation target data stored in the IMM 80. In a multiplication operation, the binary number indicated by the digital output signal b1-bm may be the multiplication result of the first operation target data stored in the IMM 80 and the second operation target data corresponding to the voltage applied to the plurality of read word lines RWL1-RWL3.

The ADC 241 may include a resistor array 2411, a comparator circuit 2413, and an encoder 2415. The comparator circuit 2413 may include the plurality of comparators (COMP).

The resistor array 2411 may include a plurality of resistors R1-R6. One end of the resistor array 2411 may receive a reference voltage Vref, and the other end may be connected to a ground GND. The reference voltage Vref may be distributed to each node formed by the plurality of resistors.

The comparator circuit 2413 may output the plurality of output signals Vout1-VoutL by comparing the voltage signal distributed to each node with the analog input signal Vin and amplifying the comparison result.

The encoder 2415 may receive a plurality of output signals Vout1-VoutL and generate bit sequences corresponding to the plurality of output signals Vout1-VoutL as digital output signals (b1-bm).

Meanwhile, the present disclosure is not limited thereto, and the ADC 241 may be implemented in various ways unlike FIG. 10, and may have various structures that generate binary data corresponding to the current value of the current based on the current provided from the first bit line BL1.

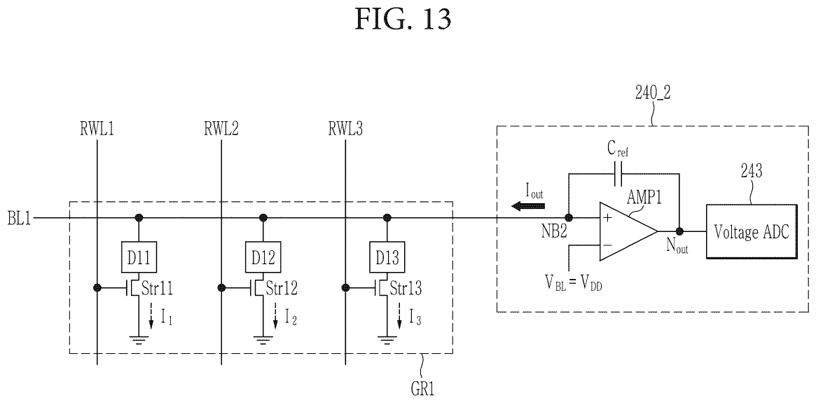

FIG. 13 is a diagram illustrating a sensing circuit according to embodiments.

Specifically, FIG. 13 illustrates a sensing circuit 240_2 connected to the first bit-cell group GR1. The sensing circuit 240_2 may convert the current output from the first bit-cell group GR1 into a voltage and convert the converted voltage into a digital value.

The sensing circuit 240_2 may include a first amplifier AMP1, a reference capacitor Cref, and a voltage ADC 243 connected to a first bit line BL1.

The first amplifier AMP1 may generate an output voltage Vout by comparing the current flowing through the input terminal with a reference voltage Vref. A first input terminal of the first amplifier AMP1 may be connected to a first bit line BL1, and a second input terminal may be connected to a power supply voltage VDD. A reference capacitor Cref may be connected to the feedback loop of the first amplifier AMP1. The output terminal of the first amplifier AMP1 may be connected to the output node Nout. The first amplifier AMP1 may transmit the output voltage Vout to the voltage ADC 243. The first amplifier AMP1 may operate to maintain a voltage of the first bit line BL1 at a constant level.

The voltage ADC 243 may convert the output voltage Vout received from the first amplifier AMP1 into a digital value. Unless otherwise stated, the description of the voltage ADC 241 described with reference to FIG. 10 may be equally applied to the voltage ADC 243.

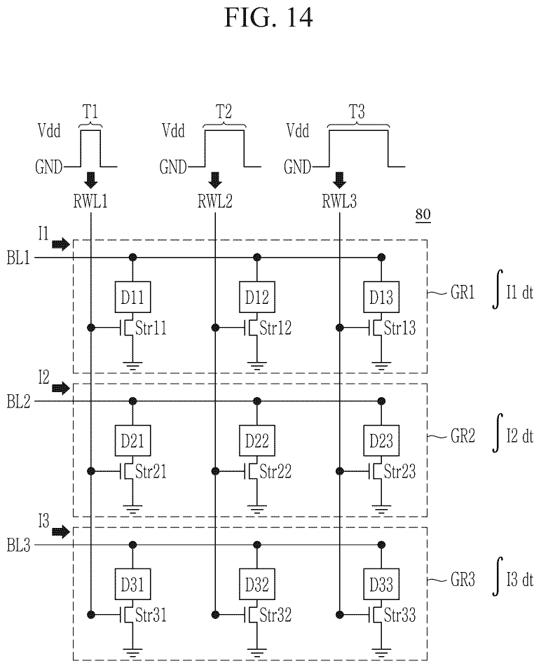

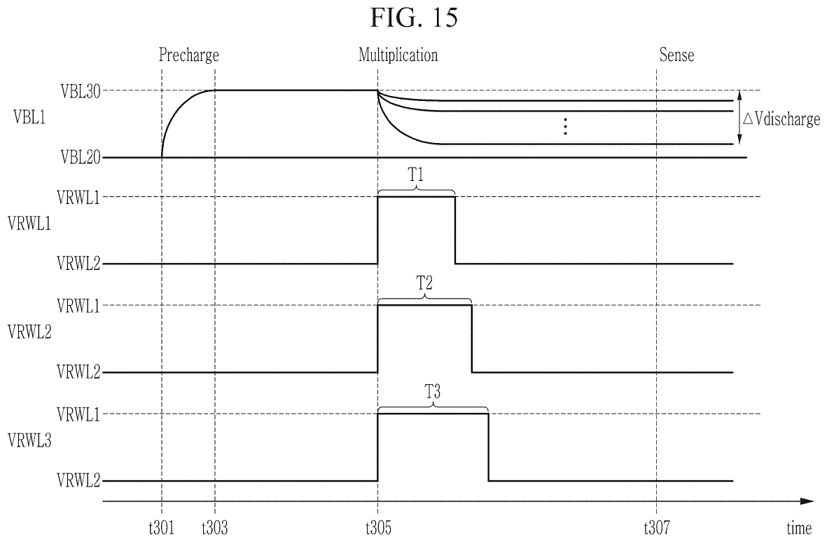

FIG. 14 is a diagram for explaining the multiplication operation of the in-memory multiplier according to FIG. 10. FIG. 15 is a diagram showing the multiplication operation of the in-memory multiplier according to FIG. 10.

According to embodiments, the IMM 80 may directly perform a multiplication operation within the memory between first operation target data stored in a bit cell and second operation target data (e.g., pulse width T or voltage A) applied externally. The second operation target data may be based on a control signal applied to the read word lines RWL1-RWL3. The result of the multiplication operation may be proportional to the magnitude or integral of the output current. For example, FIG. 14 describes a multiplication operation of a pulse width input method that multiplies data [D^{N-1}D_{N-2} . . . D₀]₂ stored in IMM 80 and a pulse width T.

First, a case of sensing a multiplication result using a sensing circuit 240_2 according to FIG. 13 is described.

At the first time point t301, the bit line sense amplifier 260 precharges the selected bit line. For example, the precharge voltage VBL30 may be a voltage higher than the supply voltage VDD or the supply voltage VDD. Accordingly, the read transistor Rtr may operate in the saturation region. Below, an example is described in which the bit line sense amplifier 260 selects the first bit line BL1.

At the second time point t303, the first bit line BL1 is precharged with a precharge voltage VBL30.

At the third time point t305, the write driver 250 may apply a pulse having a pulse width corresponding to a plurality of read word lines RWL1, RWL2, RWL3.

For example, the write driver 250 may apply a pulse of a first width T1 to a first read word line RWL1, a pulse of a second width T2 to a second read word line RWL2, and a pulse of a third width T3 to a third read word line RWL3. Each pulse may maintain the first read word line voltage VRWL1 for a corresponding time. For example, the first read word line voltage VRWL1 may be a power supply voltage VDD. The second read word line voltage VBL2 may be a ground GND.

While the write driver 250 inputs a pulse for a time corresponding to each of the plurality of read word lines RWL1, RWL2, RWL3, the current I_{Read} output through the selection transistors (Str11, Str12, Str13) connected to each bit cell D11, D12, D13 may be the sum of the output currents of the read transistors of each bit cell D11, D12, D13. Currents output from bit cells D11, D12, D13 in the same row may be summed in the direction of the read word lines RWL1, RWL2, RWL3 to form a total current I_{Read}. I_{Read} may be expressed by equation 1. Here, Iref is a reference current, and may correspond to a current value output through a read transistor of a least significant bit (LSB) cell when a logic ‘1’ (VDD) is stored in a storage node of the LSB cell.

I_{Read}=I_{N-1}+I_{N-2}+ . . . +I₀=[D_{N-1}33 2_{N-1}+D_{N-2}×2_{N-2}+ . . . +D₀×2⁰]×I_{ref}=[D_{N-1}D_{N-2} . . . D₀]₂×I_{ref} Equation 1

At this time, since I_{Read} is output only during the time T during which the first read word line voltage VRWL1 is applied to the plurality of read word lines RWL1, RWL2, RWL3, the total sum of I_{Read} output during the multiplication operation time ∫I_{Read}dt may be expressed by equation 2.

∫I_{Read}dt=[D_{N-1}D_{N-2} . . . D₀]₂×TλI_{ref} Equation 2

The result of the multiplication operation of the multi-bit information stored in the cell [D_{N-1}D_{N-2} . . . D₀]₂ and the ‘T’ input as a pulse width to the plurality of read word lines RWL1, RWL2, RWL3 may be output through ∫I_{Read}dt

At the fourth time point t307, the sensing circuit 240_1 may convert the integrated current value into a voltage and convert it into a digital value. Accordingly, the sensing circuit 240_1 may output the multiplication result.

Meanwhile, when reading out the multiplication result using the sensing circuit 240_1 according to FIG. 11, since the output current of each cell may fluctuate due to the voltage fluctuation of the first bit line BL1 during the multiplication operation, the precharge voltage VBL30 is applied at a voltage higher than the power supply voltage VDD, so that even if the voltage of the first bit line BL1 decreases, each bit cell D11, D12, D13 may maintain the saturation mode and output a constant current.

Meanwhile, a case of sensing a multiplication result using a sensing circuit 240_2 according to FIG. 13 is described.

At the first time point t301 to the second time point t303, the first amplifier AMP1 may maintain the voltage of the selected first bit line BL1 constant through a feedback loop. For example, the first bit line BL1 may be maintained at the precharge voltage VBL30 level by the first amplifier AMP1. Accordingly, each read transistor Rtr may operate in the saturation region.

At the third time point t305, the write driver 250 may apply a pulse having a pulse width corresponding to a plurality of read word lines RWL1, RWL2, RWL3.

While the write driver 250 inputs a pulse for a time corresponding to each of the plurality of read word lines RWL1, RWL2, RWL3, the current I_{Read} output through the selection transistors Str11, Str12, Str13 connected to each bit cell D11, D12, D13 may be the sum of the output currents of the read transistors of each bit cell D11, D12, D13. Currents output from bit cells D11, D12, D13 in the same row may be summed in the direction of the read word lines RWL1, RWL2, RWL3 to form a total current I_{Read}. I_{Read} may flow to the input terminal of the first amplifier AMP1.

The first amplifier AMP1 may convert the total current I_{Read} into a voltage based on the size of the reference capacitor Cref. For example, the output voltage may be expressed as the current integrated over time. The converted voltage may be expressed by Equation 3, and Equations 4 and 5 are obtained by rearranging Equation 3.

$${V}_{out} ( T ) = {V}_{initial} - \frac{1}{C} {\int }_{0}^{T} ( {I}_{1} + {I}_{2} + {I}_{3} ) dt \qquad Equation 3$$

$${V}_{out} ( T ) = {V}_{initial} - \frac{{I}_{total} \times T}{C} \qquad Equation 4$$

$$( ∵ {\int }_{0}^{T} ( {I}_{1} + {I}_{2} + {I}_{3} ) dt \approx ( {I}_{1} + {I}_{2} + {I}_{3} ) \times T = {I}_{total} \times T )$$

$$\begin{matrix}{I}_{total} \times T = {[ {D}_{N - 1} {D}_{N - 2} … {D}_{0} ]}_{2} \times T \times {I}_{ref} & Equation 5\end{matrix}$$

At the fourth time point t307, the sensing circuit 240_2 may convert the integrated current value into a voltage and convert it into a digital value. Accordingly, the sensing circuit 240_2 may output the multiplication result.

In addition, in a multiplication operation, if binary information stored in the plurality of bit cells D11, D12, D13, D21, D22, D23, D31, D32, D33 is expressed as the operation target data D of a parallel-connected read transistor, it may be expressed in a simplified form as Equation 6.

∫I_{Read}dt=[D_{N-1}×2^{N-1}+D_{N-2}×2^{N-2}+ . . . +D₀×2⁰]×T×I_{ref}=[D_{N-1}D_{N-2} . . . D₀]₂×T×I_{ref} Equation 6

In a state in which supply voltages VDD are applied to a plurality of bit lines BL1-BL3, when a voltage pulse in which a first read word-line voltage VRWL1 is applied to a plurality of read word lines RWL1-RWL3 only for a preset duration T is input, a current is output through a selected bit line BL or a ground terminal.

At this time, the sum of the currents output through the bit line during the ‘T’ time may be proportional to the product of the binary number [D_{N-1}D_{N-2} . . . D₀]₂, which is the first operation target data stored in the IMM, and the second operation target data, ‘T’.

∫I_{Read}dt of the plurality of bit cells constituting each row, i.e., the plurality of bit cells included in one bit-cell group, may be summed by Kirchhoff's law on the bit line BL or ground wiring. Accordingly, a matrix multiplication operation may be performed by inputting a voltage of a preset width to the read word lines RWL1, RWL2, RWL3 connected to the gates of the selection transistors Str11, Str12, Str13, Str21, Str22, Str23, Str31, Str32, Str33 in the IMM where the operation target data D is stored.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A memory device comprising
an in-memory operation circuit connected to a plurality of write word lines, a plurality of read word lines, and a bit line, and including a plurality of bit cells,
each of the plurality of bit cells comprise:
a first transistor having one end connected to the bit line, another end connected to a storage node, and a gate connected to a corresponding write word line among the plurality of write word lines,
at least one second transistor having one end connected to the bit line, another end connected to a first node, and a gate connected to the storage node, and
a selection transistor having one end connected to the first node, another end connected to ground, and a gate connected to a corresponding read word line among the plurality of read word lines;
wherein a turn-on current of the at least one second transistor included in the plurality of bit cells respectively corresponds to a reference current value and a multiplication value of the reference current value and a power of two.

2. The memory device of claim 1,
wherein the at least one second transistor included in each of the plurality of bit cells has a different channel width-to-length ratio W/L ratio, the ratio corresponding to the multiplication value of a reference ratio and a power of two.

3. The memory device of claim 1, wherein:
each of the plurality of bit cells includes the at least one second transistor in a number corresponding to a power of two, and
the number of the at least one second transistor included in the plurality of bit cells is different from one another.

4. The memory device of claim 1, further comprising:
a bit line sense amplifier providing a voltage to the bit line; and
a word line driver that provides voltage to the plurality of write word lines and the plurality of read word lines.

5. The memory device of claim 4,
wherein:
the bit line sense amplifier applies to the bit line a multi-level voltage having at least two voltage levels based on first operation target data in a first period, and
the word line driver applies a first write word-line voltage to a first write word line, connected to a first bit cell among the plurality of write word lines, during the first period, and the first bit cell among the plurality of bit cells stores information corresponding to a digit of the first operation target data.

6. The memory device of claim 5,
wherein:
in a multiplication operation for the first operation target data and second operation target data,
the word line driver provides to a second write word line, connected to a second bit cell among the plurality of write word lines, a pulse having a width corresponding to the second operation target data, and
the second bit cell outputs to the bit line a first output current based on a product of information corresponding to a digit of the first operation target data, the reference current value, and the second operation target data.

7. The memory device of claim 6, further comprising
a sensing circuit connected to the bit line, the sensing circuit including a voltage ADC configured to convert the first output current into a voltage and convert the voltage into a digital value.

8. The memory device of claim 1,
wherein the first transistor includes, as a channel material, at least one oxide semiconductor selected from indium gallium zinc oxide InGaZnO; IGZO, indium oxide In₂O₃, indium tungsten oxide IWO, indium gallium oxide IGO, indium tin oxide ITO, indium gallium zinc tin oxide IGZTO, indium tin zinc oxide ITZO, indium zinc tin oxide IZTO, aluminum zinc oxide AZO, and indium aluminum zinc oxide IAZO.

9. A memory device comprising:
a plurality of read word lines;
a plurality of bit lines;
a plurality of bit cells respectively connected to the plurality of bit lines and including storage nodes; and
a plurality of selection transistors having gates connected to the plurality of read word lines, one ends connected to first nodes of the plurality of bit cells, and other ends connected to a ground,
wherein:
a selected first bit cell among the plurality of bit cells stores first information corresponding to a digit of first operation target data in the storage node, and
when a pulse having a width corresponding to second operation target data is applied to a first read word line connected to a gate of a first selection transistor corresponding to the first bit cell, the first bit cell outputs, to a first bit line corresponding to the first bit cell, a first output current based on a product of the first information, a reference current value, and the second operation target data.

10. The memory device of claim 9, further comprising
a plurality of write word lines,
wherein the first bit cell comprises:
a first transistor having one end connected to the first bit line, another end connected to the storage node, and a gate connected to a corresponding one of the plurality of write word lines; and
at least one second transistor having one end connected to the first bit line, another end connected to the first node, and a gate connected to the storage node.

11. The memory device of claim 10,
wherein each of the at least one second transistor has a different channel width-to-length ratio (W/L ratio), and the ratio corresponds to a product of a reference ratio and a power of two.

12. The memory device of claim 10,
wherein current values of turn-on currents of the at least one second transistor included in the plurality of bit cells respectively correspond to a reference current value and multiplication values of the reference current value and powers of two.

13. The memory device of claim 9,
wherein the first bit cell is configured to store a multi-level voltage, the multi-level voltage including at least two bits of data.

14. The memory device of claim 9,
wherein:
a plurality of bit cells connected to a same bit line among the plurality of bit cells are grouped as a bit-cell group, and
output currents of the plurality of bit cells included in the bit-cell group are summed according to Kirchhoff's law.

15. The memory device of claim 9, further comprising
a sensing circuit connected to the bit line,
wherein the sensing circuit comprises a first amplifier configured to integrate the first output current and convert the integrated current into a voltage, and a voltage analog-to-digital converter (ADC) configured to convert the voltage into a digital value.

16. A computing method of a memory device comprising a plurality of bit lines, a plurality of bit cells respectively connected to the plurality of bit lines and including storage nodes, and a plurality of selection transistors connected in series between the plurality of bit cells and a ground node, the computing method comprising:
storing charge in each storage node of a plurality of bit cells by applying a voltage corresponding to first operation target data to a plurality of bit lines,
applying a pulse having a width corresponding to second operation target data to a read word line connected to a gate of a selected selection transistor among the plurality of selection transistors, and
sensing an operation result based on a first output current output from a first bit line selected from among the plurality of bit lines.

17. The computing method of claim 16,
wherein the memory device further comprises a plurality of write word lines respectively connected to the plurality of bit cells, and the computing method further comprises:
applying, to a first bit line among the plurality of bit lines, a multi-level voltage having at least two voltage levels based on the first operation target data; and
applying a first write word-line voltage to a first write word line connected to a first bit cell corresponding to a digit of the first operation target data, to turn on a first transistor disposed between the first bit line and the storage node.

18. The computing method of claim 16,
wherein the first operation target data is stored as a multi-level voltage, the multi-level voltage including at least two bits of data.

19. The computing method of claim 16,
further comprising precharging the first bit line to a precharge voltage higher than a supply voltage before the applying of the pulse.

20. The computing method of claim 16,
wherein the sensing of the operation result comprises:
integrating the first output current and converting the integrated current into a voltage, and converting the voltage into a digital value through a voltage ADC.
